(19) United States
(12) Patent Application Publication
(10) Pub. No.: US 2019/0092798 A1
(43) Pub. Date: Mar. 28, 2019

(54) ORGANIC METAL COMPLEX, METHOD FOR PREPARING THE SAME, AND LIGHT-EMITTING ELEMENT INCLUDING THE SAME

(71) Applicants: AAC Microtech IChangzhoul Co., Ltd., Chanzhou City OT (CN); Nanjing Tech University, Nanjing OT (CN)

(72) Inventors: Xiaochun HANG, Shenzhen (CN); Yin ZHANG, Shenzhen (CN); Changmei LIU, Shenzhen (CN); Zhikuan CHEN, Shenzhen (CN); Tengda MA, Shenzhen (CN); Jiuzhou LIU, Shenzhen (CN); Shaohai Chen, Shenzhen (CN)

(21) Appl. No.: 15/883,147

(22) Filed: Jan. 30, 2018

(30) Foreign Application Priority Data
Sep. 22, 2017 (CN) 201710866603.3

(51) Int. Cl. C07F 15/00; H01L 51/00; H01L 51/50

(52) U.S. Cl. CPC C07F 15/0033; H01L 51/5016; H01L 51/0085

(57) ABSTRACT

Provided are an organic metal complex, its preparation method and light-emitting element containing the complex. The organic metal complex is selected from compounds shown as general formula I and combinations thereof. The ligand containing pyridine unit is introduced into the cyclometalated iridium(III) organic metal complex, and the obtained iridium(III) heterocomplex has a luminous range from near-infrared light to blue light, so that the ppz-Ir structure, which is originally non-luminous, can emit light at room temperature with advantages of wide application scope of spectrum and low cost of massive production.

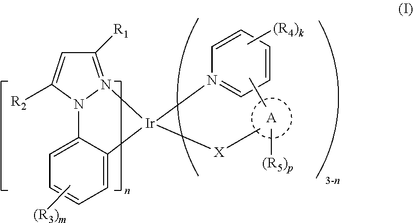

### TECHNICAL FIELD

The present application relates to the technical field of organic light-emitting materials and, more particularly, to an organic metal complex, a method for preparing the organic metal complex, and a light-emitting element including the organic metal complex.

### BACKGROUND

The organic light-emitting diode (OLED) refers to a light-emitting element in which light-emitting materials of small organic molecules, organic metal complexes, or polymer molecules convert electric energy into optical energy under an action of a forward bias voltage electric field. OLED has characteristics of fast response, low driving voltage, high luminous efficiency, high resolution, high contrast, wide viewing angle and self-illumination and needs no backlight, and has attracted wide attentions from both academic circles and industrial circles. In addition, OLED can be formed on cheap glass, metal, or even flexible plastics, thus has advantages of low cost, simple production process, and capability of large area production. OLED has become a new generation of full-color display and illumination technology, and has a wide and vast application prospect in the full-color display and flat solid-state lighting fields.

The light-emitting materials used in the early OLED are mainly small molecular organic fluorescent materials, which can only utilize molecules in a singlet state after electron excitation, and it is demonstrated by the spin-statistics quantum theory that its internal quantum efficiency is 25%. 75% of excited molecules are in an excited triplet state and can jump back to the ground state and emit phosphorescence by a radiative transition. It is generally thought that the organic small molecule compound hardly emits phosphorescence at room temperature until a phosphorescent electroluminescence phenomenon of the metal organic complex molecular materials at room temperature is found. A strong spin-orbit coupling of heavy metal atoms can effectively facilitate electron intersystem crossing (ISC) from the singlet state to the triplet state, so that the OLED can sufficiently use all the electron-excited singlet and triplet excitons and the theoretical internal quantum efficiency of the luminous materials can reach to 100%. Thus, a research of the organic light-emitting materials enters into a brand new age.

Cyclometalated iridium(III) complex phosphorescent materials are a kind of early researched phosphorescent metal organic complexes. A significant progress had been achieved after nearly 20 years' research and development. The cyclometalated iridium(III) complex phosphorescent materials have two types of molecular structures, i.e., homoleptic structure and heteroleptic structure. An ancillary ligand (for example acetylacetone) in iridium(III) heteroleptic coordination compound luminous materials generally won't affect the energy levels and luminous efficiency of an coordination of iridium(III) and luminous ligand. Therefore, both lumination of homoleptic and luminiation of heteroleptic are determined by a coordination part of the luminous ligand and iridium(III). The cyclometalated iridium(III) complex phosphorescent material having a heteroleptic structure generally has a high synthetic efficiency, which can decrease cost of production and purification of the materials. Red and green phosphorescent materials of the cyclometalated iridium(III) complex are already applied in commercial display elements, while a stable and high-efficient, blue phosphorescent material of the cyclometalated iridium(III) complex is not yet developed.

### BRIEF DESCRIPTION OF DRAWINGS

FIG. 1 illustrates luminescence spectra of Ir-1 in a dichloromethane solution at room temperature;

FIG. 2 illustrates luminescence spectra of Ir-2 in a dichloromethane solution at room temperature;

FIG. 3 illustrates luminescence spectra of Ir-3 in a dichloromethane solution at room temperature;

FIG. 4 illustrates luminescence spectra of Ir-4 in a dichloromethane solution at room temperature;

FIG. 5 illustrates luminescence spectra of Ir-5 in a dichloromethane solution at room temperature;

FIG. 6 illustrates luminescence spectra of Ir-8 in a dichloromethane solution at room temperature;

FIG. 7 illustrates luminescence spectra of Ir-9 in a dichloromethane solution at room temperature;

FIG. 8 illustrates luminescence spectra of Ir-10 in a dichloromethane solution at room temperature;

FIG. 9 illustrates an electron cloud model of Ir(ppz)₃ at S₁ excitation state;

FIG. 10 illustrates an electron cloud model of Ir(ppz)₂(ImPy) at S₁ excitation state; and

FIG. 11 illustrates a structural schematic diagram of a light-emitting element according to an embodiment of the present disclosure.

### REFERENCE SIGNS

10—light-emitting element;
11—first electrode;
12—hole transportation layer;
13—light-emitting layer;
14—electron transportation layer;
15—second electrode.

### DESCRIPTION OF EMBODIMENTS

The present disclosure is described in further detail with reference to the accompanying drawings and embodiments. It should be understood that the embodiments are merely used to illustrate the present disclosure but not to limit the scope of the present disclosure.

One embodiment of the present disclosure provides an organic metal complex, which is selected from a group consisting of compounds as represented by general formula I and combinations thereof;

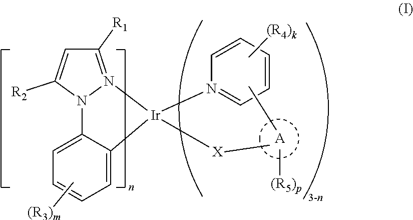

wherein R₁, R₂, R₃, R₄ and R₅ are independently selected from a group consisting of hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl;

wherein R₂ can be connected with adjacent aryl or substituent to form a ring, and the ring formed can be an aromatic ring, an alicyclic ring, a heteroaromatic ring, or a heteroalicyclic ring;

similarly, R₄ can be connected with adjacent aryl or substituent to form a ring, and the ring formed can be an aromatic ring, an alicyclic ring, a heteroaromatic, or a heteroalicyclic ring;

similarly, R₅ can be connected with adjacent aryl or substituent to form a ring, and the ring formed can be an aromatic ring, an alicyclic ring, a heteroaromatic ring, or a heteroalicyclic ring; X represents carbon atom, oxygen atom or nitrogen atom, structure A is selected from a group consisting of substituted or unsubstituted C₁-C₆ alkylene, substituted or unsubstituted C₃-C₃₆ heteroaromatic ring, and substituted or unsubstituted C₆-C₃₆ aromatic ring, and structure A is connected with or fused to a pyridine ring; wherein, “connected with” refers to directly connection by a covalent bond, and “fused to” means that structure A and the pyridine ring share a side to form a fused structure;

X can be a group different from structure A and connected with structure A by covalent bond; or X can be an atom in structure A or a group which participates in forming structure A, mainly participating in forming an aromatic ring or a heteroaromatic ring;

n is 1 or 2, and m, k, and p are integers independently selected from 1, 2, 3 and 4;

when m is greater than 1 and R₃ is neither hydrogen nor deuterium, (R₃)ₘ can include a situation that (R₃)ₘ forms an aromatic ring or a heteroaromatic ring fused to a benzene ring;

when k is greater than 1 and R₄ is neither hydrogen nor deuterium, (R₄)ₖ can include a situation that (R₄)ₖ forms an aromatic ring or a heteroaromatic rings fused to a pyridine ring; and

each substituent is independently selected from a group consisting of halogen, C₁-C₆ alkyl, C₁-C₆ deuterated alkyl and combinations thereof; the substituent herein includes substituents of the above-mentioned substituted groups, i.e., the substituted C₁-C₆ alkyl, the substituted C₁-C₆ deuterated alkyl, the substituted C₃-C₃₆ heteroaryl, the substituted C₆-C₃₆ aryl, the substituted C₃-C₃₆ deuterated heteroaryl, the substituted C₆-C₃₆ deuterated aryl, the substituted C₁-C₆ alkylene, the substituted C₃-C₃₆ heteroaromatic ring, and the substituted C₆-C₃₆ aromatic ring;

wherein the halogen includes fluorine, chlorine and bromine; preferably, the halogen is fluorine.

In the embodiments of the present disclosure, the C₁-C₆ alkyl can include methyl, ethyl, n-propyl, isopropyl, n-butyl, isobutyl, tert-butyl, n-amyl, 1-methylbutyl, 2-methylbutyl, 3-methylbutyl, 1,2-dimethylpropyl, 2,3-dimethylpropyl, 1-ethylpropyl, cyclopentyl, cyclohexyl, 2-methyl-3-pentyl, 3,3-dimethyl-2-butyl, etc.

In the embodiments of the present disclosure, the deuterated alkyl refers to a substituent formed by substituting hydrogen atom of alkyl with deuterium atom; the deuterated aryl refers to a substituent formed by substituting hydrogen atom of aryl with deuterium atom; and the deuterated heteroaryl refers to a substituent formed by substituting hydrogen atom of heteroaryl with deuterium atom.

In the embodiments of the present disclosure, a ligand containing a pyridine unit is introduced into the cyclometalated iridium(III) organic metal complex, and the obtained iridium(III) heterocomplex has a luminous range from near-infrared light to blue light, so that the ppz-Ir structure, which is originally non-luminous, can emit light at room temperature with advantages of wide application scope of spectrum and low cost of massive production. The organic metal complex in the embodiments of the present disclosure is suitable for use as an electroluminescent material of a phosphorescent light emitting element in display or lighting application.

Optionally, when X is carbon atom, structure A is selected from a group consisting of substituted or unsubstituted C₃-C₃₆ heteroaromatic ring and substituted or unsubstituted C₆-C₃₆ aromatic ring, and X is an atom in structure A and participates in forming the heteroaromatic ring or aromatic ring in structure A;

when X is nitrogen atom, structure A is selected from a group consisting of substituted or unsubstituted C₃-C₃₆ heteroaromatic ring, and X is an atom in structure A and participates in forming the heteroaromatic ring in structure A;

when X is oxygen atom, structure A is selected from a group consisting of substituted or unsubstituted C₁-C₆ alkylene, substituted or unsubstituted C₃-C₃₆ heteroaromatic ring, and substituted or unsubstituted C₆-C₃₆ aromatic ring, and X can be a group different from structure A and connected with structure A by a covalent bond.

When X is oxygen atom, an improvement of the organic metal complex represented by general formula I is obtained, which is represented by general formula IA:

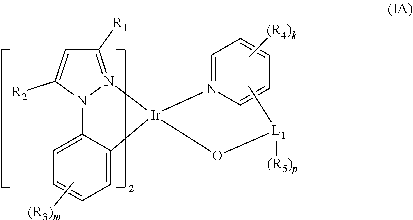

wherein L₁ is selected from a group consisting of substituted or unsubstituted C₁-C₆ alkylene, substituted or unsubstituted C₃-C₃₆ heteroaromatic ring, and substituted or unsubstituted C₆-C₃₆ aromatic ring; and L₁ is connected with or fused to a pyridine ring.

Furthermore, optionally, the organic metal complex represented by formula IA can be selected from a group consisting of complexes represented by general formula IAa and general formula IAb and combinations thereof,

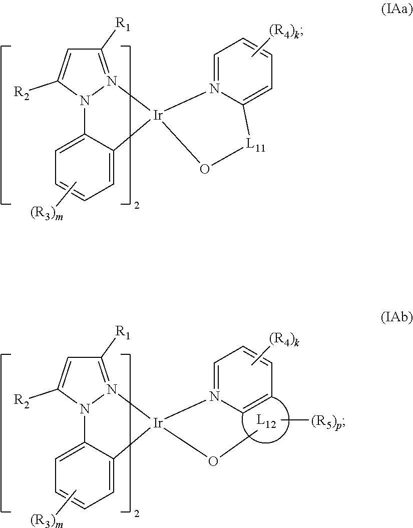

wherein L₁₁ is selected from a group consisting of substituted or unsubstituted C₁-C₆ alkylene, L₁₂ is selected from a group consisting of substituted or unsubstituted C₃-C₁₈ heteroaromatic ring and substituted or unsubstituted C₆-C₁₈ aromatic ring; and

each substituent is independently selected from a group consisting of halogen, C₁-C₆ alkyl, C₁-C₆ deuterated alkyl and combinations thereof; the substituent herein includes substituents of the above-mentioned substituted groups, i.e., the substituted C₁-C₆ alkylene, the substituted C₃-C₁₈ heteroaromatic ring and the substituted C₆-C₁₈ aromatic ring.

When k is greater than 1 and R₄ is neither hydrogen nor diplogen, (R₄)ₖ can include a situation that (R₄)ₖ forms an aromatic ring or a heteroaromatic ring fused to a benzene ring.

When X is a carbon atom and participates in forming a benzene ring, an improvement of the organic metal complex represented by general formula I is obtained, which is specifically represented by general formula IB:

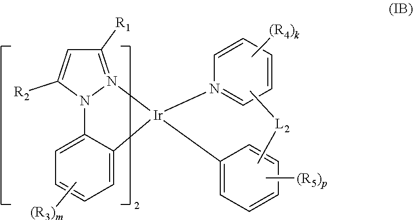

wherein L₂ is selected from a group consisting of substituted or unsubstituted C₁-C₆ alkylene, substituted or unsubstituted C₃-C₃₆ heteroaromatic ring and substituted or unsubstituted C₆-C₃₆ aromatic ring; L₂ is connected with or fused to a pyridine ring and L₂ is connected with or fused to a benzene ring; and

each substituent is independently selected from a group consisting of halogen, C₁-C₆ alkyl, C₁-C₆ deuterated alkyl and combinations thereof; the substituent herein includes substituents of the above-mentioned substituted groups, i.e., the substituted C₁-C₆ alkylene, the substituted C₃-C₃₆ heteroaromatic ring and the substituted C₆-C₃₆ aromatic ring.

Furthermore, optionally, the organic metal complex represented by formula IB can be selected from a group consisting of complexes represented by general formula IBa, general formula IBb general formula IBc, and combinations thereof,

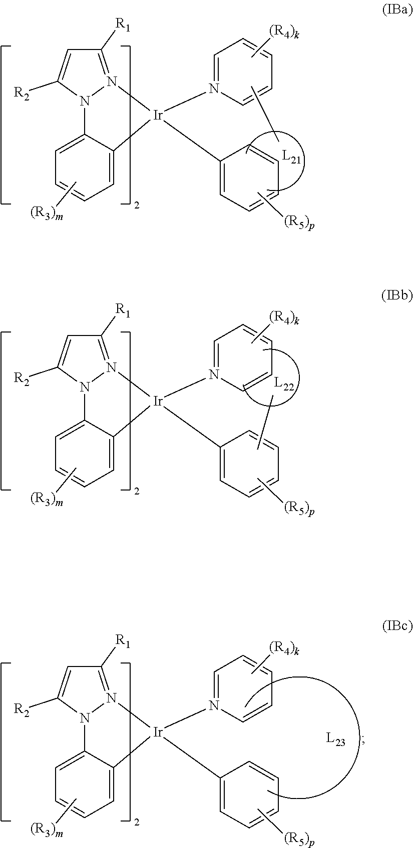

wherein L₂₁, L₂₂ and L₂₃ are independently selected from a group consisting of substituted or unsubstituted C₁-C₆ alkylene, substituted or unsubstituted C₃-C₁₈ heteroaromatic ring, and substituted or unsubstituted C₆-C₁₈ aromatic ring;

in IBa, L₂₁ is fused to a benzene ring;

in IBb, L₂₂ is fused to a pyridine ring;

in IBc, L₂₃ is fused to both a pyridine ring and a benzene ring; and

each substituent is independently selected from a group consisting of halogen, C₁-C₆ alkyl, C₁-C₆ deuterated alkyl and combinations thereof; the substituent herein includes substituents of the above-mentioned substituted groups, i.e., the substituted C₁-C₆ alkylene, the substituted C₃-C₁₈ heteroaromatic ring, and the substituted C₆-C₁₈ aromatic ring.

When X is a nitrogen atom and participates in forming a five membered heterocyclic ring, an improvement of the organic metal complex represented by general formula I is obtained, which is specifically represented by general formula IC:

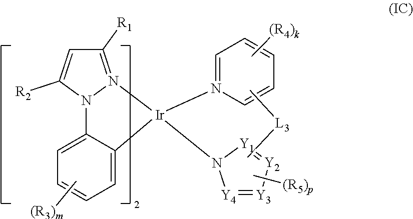

wherein Y₁, Y₂, Y₃ and Y₄ are independently nitrogen atom or carbon atom;

L₃ is selected from a group consisting of a dummy atom, substituted or unsubstituted C₁-C₆ alkylene, substituted or unsubstituted C₃-C₃₆ heteroaromatic ring, and substituted or unsubstituted C₆-C₃₆ aromatic ring; the dummy atom means that L₃ is non-existing and the five membered heterocyclic ring is directly connected with the pyridine ring;

L₃ is connected with or fused to the pyridine ring and L₃ is connected with or fused to the five membered heterocyclic ring

R₅ is selected from a group consisting of hydrogen, deuterium, substituted or unsubstituted C₁-C₆ alkyl, substituted or unsubstituted C₁-C₆ deuterated alkyl, substituted or unsubstituted C₆-C₃₆ aryl and substituted or unsubstituted C₆-C₃₆ deuterated aryl, and is optionally connected with an adjacent aryl or substituent;

p is an integer selected from 1, 2, 3 and 4; and

each substituent is independently selected from a group consisting of halogen, C₁-C₆ alkyl, C₁-C₆ deuterated alkyl and combinations thereof; the substituent herein includes substituents of the above-mentioned substituted groups, i.e., the substituted C₁-C₆ alkylene, the substituted C₃-C₃₆ heteroaromatic ring, and the substituted C₆-C₃₆ aromatic ring.

Optionally, the organic metal complex represented by formula IC can be selected from a group consisting of complexes represented by general formula ICa and general formula ICb and combinations thereof,

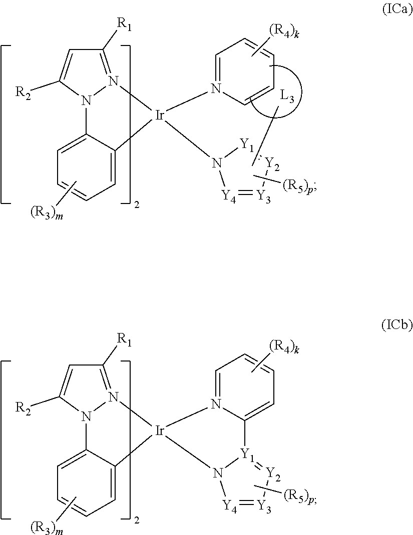

wherein L₃₁ is selected from a group consisting of substituted or unsubstituted C₃-C₁₈ heteroaromatic ring and substituted or unsubstituted C₆-C₁₈ aromatic ring; and each substituent is independently selected from a group consisting of halogen, C₁-C₆ alkyl, C₁-C₆ deuterated alkyl and combinations thereof; the substituent herein includes substituents of the above-mentioned substituted groups, i.e., the substituted C₃-C₁₈ heteroaromatic ring and the substituted C₆-C₁₈ aromatic ring.

Optionally, in the above-described general formulas, the ligand on the right side of the general formulas is selected from a group consisting of structures as follows:

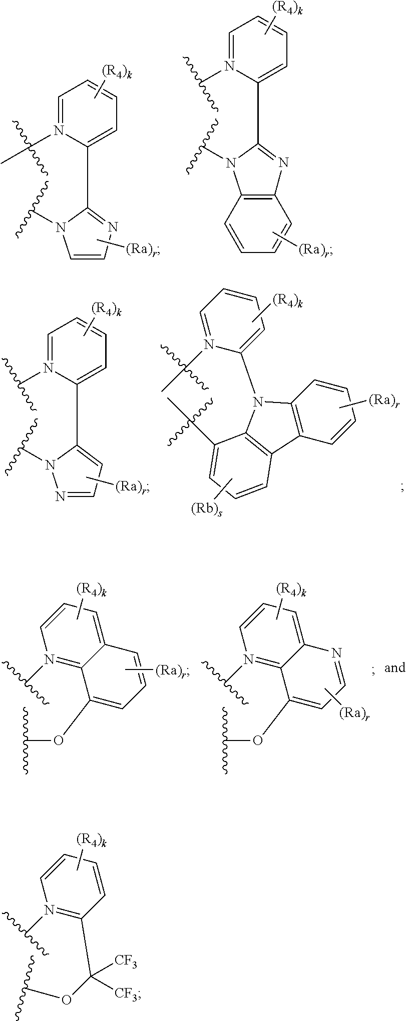

wherein Rₐ and R_{b} are selected from a group consisting of hydrogen, diplogen, substituted or unsubstituted C₁-C₆ alkyl, substituted or unsubstituted C₁-C₆ deuterated alkyl, substituted or unsubstituted C₆-C₃₆ aryl, and substituted or unsubstituted C₆-C₃₆ deuterated aryl;

Rₐ and R_{b} are independently and optionally connected with an adjacent aryl or substituent; i.e., Rₐ and R_{b} can be independently connected with an adjacent aryl or substituent to form a ring and the ring formed can be an aromatic ring, an alicyclic ring, a heteroaromatic ring or a heteroalicyclic ring;

r and s are integers independently selected from 1, 2, 3 and 4;

when r is greater than 1 and Rₐ is neither hydrogen nor diplogen, (Rₐ)ᵣ can include a situation that (Rₐ)ᵣ forms an aromatic ring or a heteroaromatic ring fused to a benzene ring; and

when s is greater than 1 and R_{b} is neither hydrogen nor diplogen, (R_{b})ₛ can include a situation that (R_{b})ₛ forms an aromatic ring or a heteroaromatic ring fused to a pyridine ring.

Optionally, Rₐ and R_{b} are independently selected from a group consisting of hydrogen, deuterium, C₁-C₆ alkyl, C₁-C₆ deuterated alkyl, C₆-C₁₈ aryl, C₆-C₁₈ deuterated aryl, C₆-C₁₈ aryl substituted with C₁-C₆ alkyl, C₆-C₁₈ aryl substituted with C₁-C₆ deuterated alkyl, and C₆-C₁₈ deuterated aryl substituted with C₁-C₆ deuterated alkyl.

Optionally, the ligand on the right side of the above general formulas is selected from but not limited to a group consisting of structures as follows:

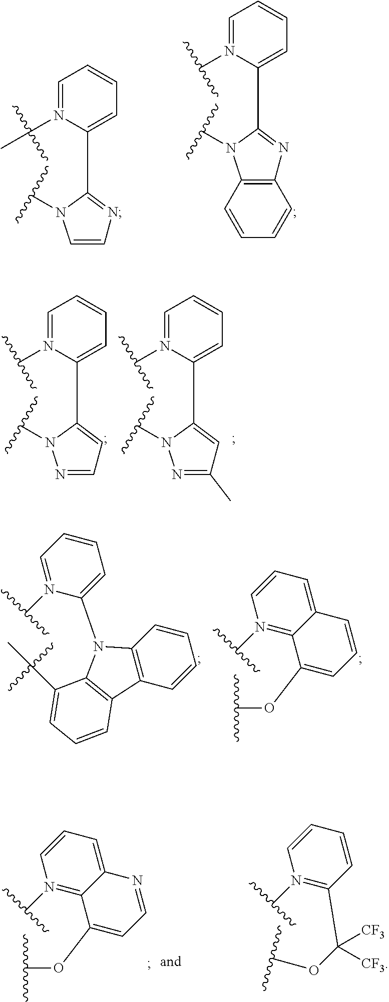

Optionally, the ligand on the left side of the above general formulas is selected from a group consisting of structures as follows:

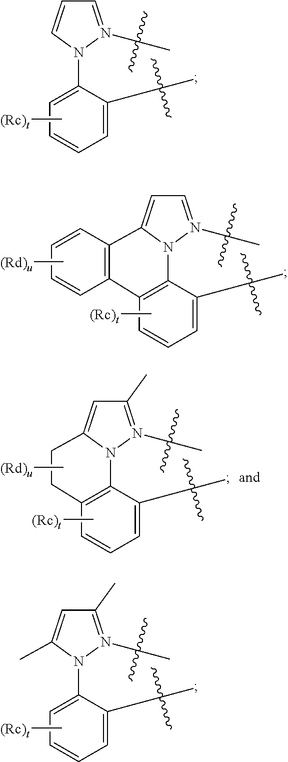

wherein R_{c} and R_{d} are selected from a group consisting of hydrogen, deuterium, substituted or unsubstituted C₁-C₆ alkyl, substituted or unsubstituted C₁-C₆ deuterated alkyl, substituted or unsubstituted C₆-C₃₆ aryl, and substituted or unsubstituted C₆-C₃₆ deuterated aryl;

R_{c} and R_{d} are independently and optionally connected with an adjacent aryl or substituent; i.e., R_{c} and R_{d} are independently connected with an adjacent aryl or substituent to form a ring and the formed ring can be an aromatic ring, an alicyclic ring, a heteroaromatic ring or a heteroalicyclic ring;

t and u are integers independently selected from a group consisting of 1, 2, 3 and 4;

when t is greater than 1 and R_{c} is neither hydrogen nor diplogen, R_{c} can include an aromatic ring or a heteroaromatic ring fused to a benzene ring; and

when u is greater than 1 and R_{d} is neither hydrogen nor diplogen, R_{d} can include an aromatic ring or a heteroaromatic ring fused to a benzene ring.

Further optionally, R_{c} and R_{d} are independently selected from a group consisting of hydrogen, deuterium, C₁-C₆ alkyl, C₁-C₆ deuterated alkyl, C₆-C₁₈ aryl, C₆-C₁₈ deuterated aryl, C₆-C₁₈ aryl substituted with C₁-C₆ alkyl, C₆-C₁₈ aryl substituted with C₁-C₆ deuterated alkyl, and C₆-C₁₈ deuterated aryl substituted with C₁-C₆ deuterated alkyl.

Optionally, the ligand on the left side of the general formulas is selected from but not limited to structures as follows:

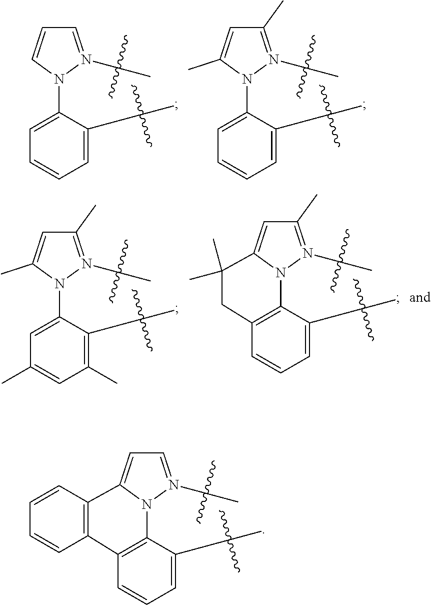

Optionally, the organic metal complex in the embodiments of the present disclosure is selected from but not limited to a group consisting of compounds shown as chemical formulas as follows:

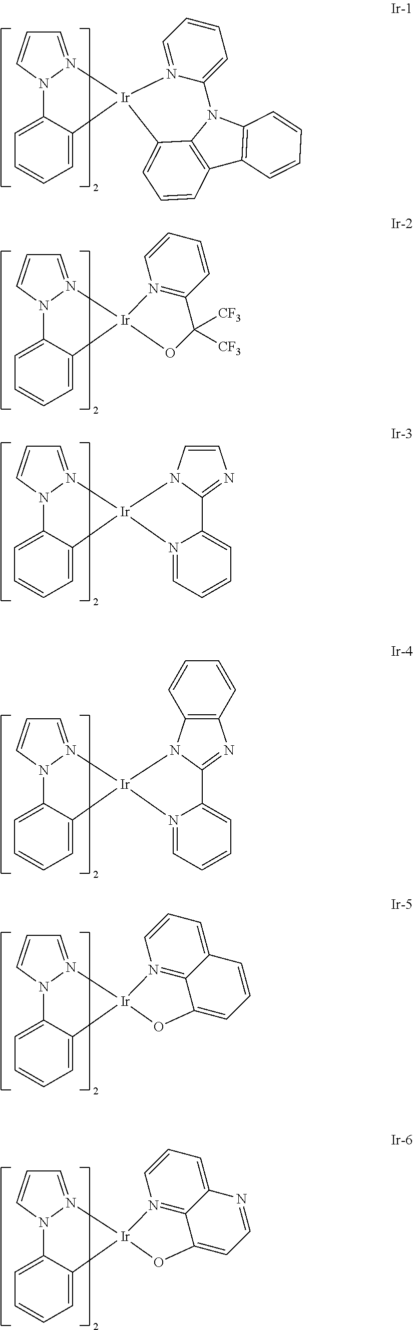

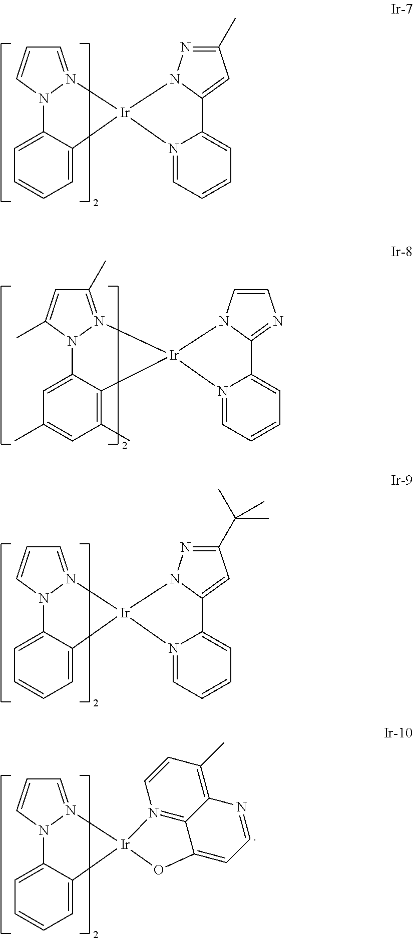

One embodiment of the present disclosure further provides a method for preparing the organic metal complex, including at least steps as follows:

reacting a precursor L with iridium chloride (IrCl₃) to obtain a dimer, and reacting the dimer with a ligand compound to obtain a compound represented by general formula I; and

a chemical reaction equation of the method is shown as below:

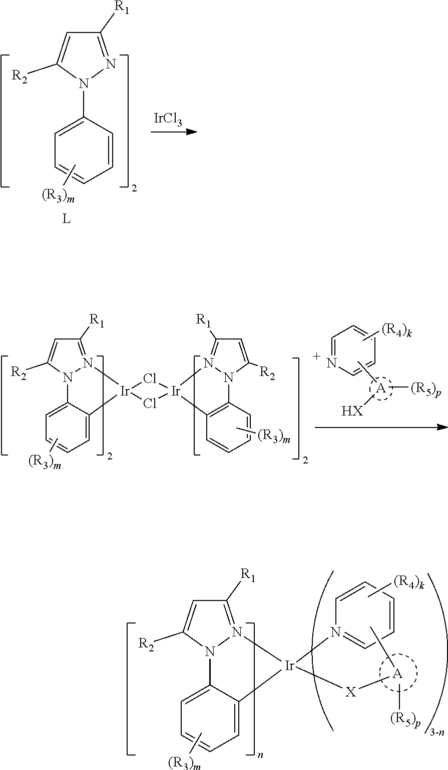

The embodiments of the present disclosure are further interpreted with specific synthesis examples as follows.

### Synthesis Example 1: Synthesis and Structural Characterization of Ir-1

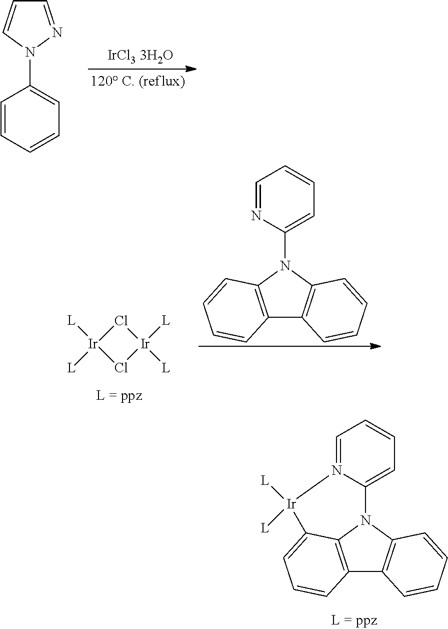

N-phenylpyrazole, ethylene glycol monomethyl ether, deionized water and IrCl₃.3H₂O are added into a round-bottom flask to obtain a solution, and the solution obtained is air exhausted for three times under a nitrogen atmosphere and then refluxed for 12 h. After finishing the reaction, the reaction mixture is cooled to room temperature, and then filtered and desolventized to obtain a solid dimer, and then the solid dimer is filtered and washed with n-hexane and diethyl ether and then is dried in air.

The dimer (0.1 g, 0.10 mmol, 1.0 eq), a ligand (0.3 g, 1.2 mmol, 12.0 eq), potassium carbonate (0.3 g, 2.2 mmol, 22.0 eq), glycerin (3 mL) are added into a sealed tube (60 mL) and heated to 200° C., the mixture is allowed to react for 14 h and then cooled, and then water is added. Mixture is extracted with dichloromethane (DCM), the organic phase is dried and purified through chromatography with the eluent of PE:EA=10:1 (volume ratio) to obtain 60 mg light yellow solid with a yield of 42%.

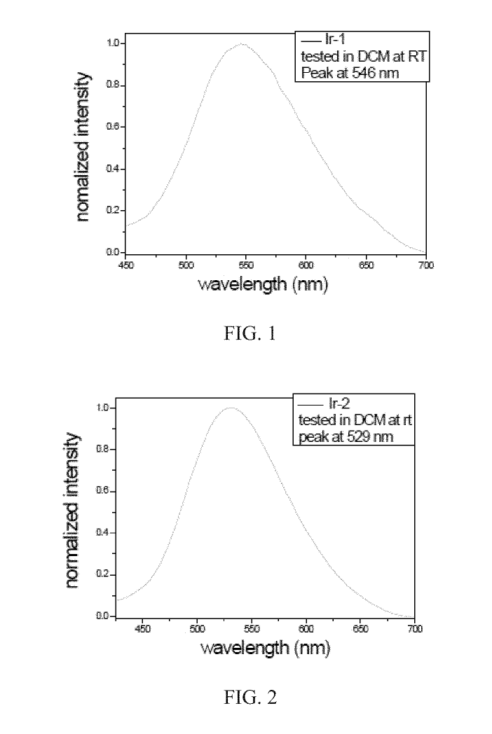

A luminous spectrum of the obtained complex in DCM at room temperature is shown in FIG. 1, in which a main emission peak is at 546 nm. An emission peak wavelength of the obtained complex is 504 nm in a polymethyl methacrylate (PMMA) thin film. Thus, the obtained complex is a blue-green light material.

¹H-NMR (300 MHz, d⁶-DMSO, δ): 6.35-6.38 (d, 1H), 6.52-6.56 (d, 3H), 6.60 (m, 2H), 6.63-6.73 (m, 2H), 6.86-6.96 (m, 4H), 7.28-7.42 (m, 5H), 7.57-7.59 (d, 1H), 7.83-8.04 (m, 5H), 8.60-8.65 (d, 2H).

A purity tested by ultra performance liquid chromatography (UPLC) is 99.79%. ESI MASS: 1116.87, [M]⁺.

### Synthesis Example 2: Synthesis and Structural Characterization of Ir-2

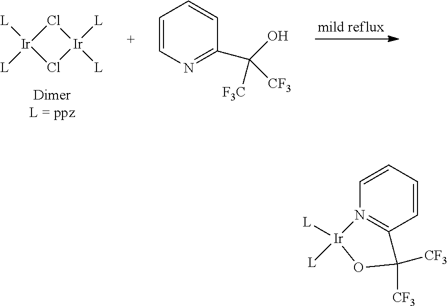

Dimer (0.1 g, 0.10 mmol, 1.0 eq), ligand (0.2 g, 0.82 mmol, 8.2 eq), potassium carbonate (0.3 g, 2.2 mmol, 22 eq), and ethylene glycol monomethyl ether (2 mL) are added into a sealed tube (60 ml), and the mixture is bubbled with nitrogen for about 15 min and then heated to 135° C., allowed to react for 20 h, cooled to room temperature, filtered, and then rinsed with 10 mL water, 10 mL ethyl alcohol and 10 mL petroleum ether, respectively, thereby obtaining 0.09 g yellow solid with a yield of 62%.

A luminous spectrum of the obtained complex in DCM at room temperature, is shown in FIG. 2, in which a main emission peak is at 529 nm. Thus, the obtained complex is a green light material.

¹H-NMR (300 MHz, d⁶-DMSO) δ: 5.92-5.95 (d, 1H), 6.03-6.05 (d, 1H), 6.58-6.70 (m, 3H), 6.82-6.91 (m, 4H), 7.49-7.57 (m, 3H), 7.72 (s, 1H), 7.82-7.85 (d, 1H), 8.00 (d, 1H), 8.05-8.09 (t, 1H), 8.72-8.74 (d, 1H), 8.79-8.80 (d, 1H)∘ ESI MASS: 724.1, [M]⁺.

### Synthesis Example 3: Synthesis and Structural Characterization of Ir-3

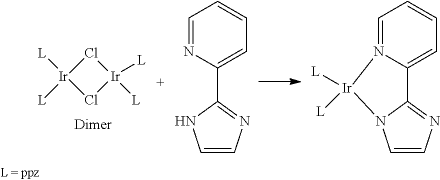

Dimer (0.1 g, 0.10 mmol, 1.0 eq), ligand (0.2 g, 1.4 mmol, 14.0 eq), potassium carbonate (0.3 g, 2.2 mmol, 22.0 eq), and ethylene glycol monomethyl ether (2 mL) are added into a seal tube (60 mL), the seal tube is air replaced with nitrogen for 5 times, then the mixture is heated to 120° C., allowed to react for 20 h, cooled to room temperature, filtered, and then rinsed with 10 mL water, 10 mL ethyl alcohol and 10 mL petroleum ether, respectively, and finally the raw product is purified through chromatography with the eluent of PE:EA=10.1 (volume ratio) to obtain 60 mg yellow solid with a yield of 48% and a UPLC purity of 100%.

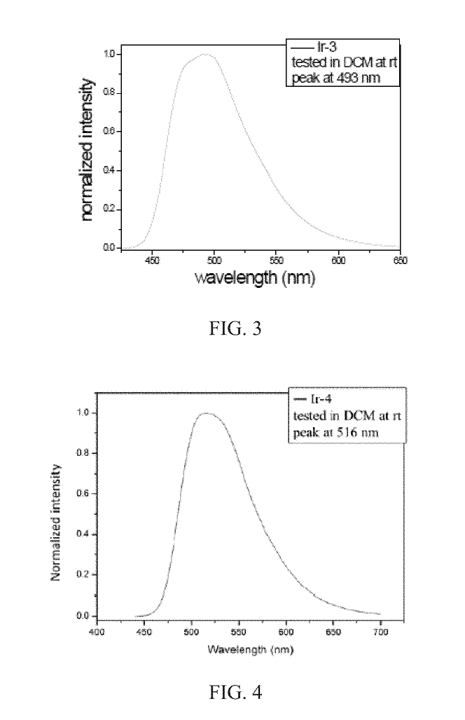

A luminous spectrum of the obtained complex in DCM at room temperature is shown in FIG. 3, in which a main emission peak is at 493 nm. Thus, the obtained complex is a blue-green light material.

¹H-NMR (300 MHz, CDCl₃) δ: 6.38-6.44 (m, 3H), 6.50-6.52 (d, 1H), 6.63 (s, 1H), 6.75-7.00 (m, 7H), 7.19-7.22 (t, 3H), 7.65-7.68 (t, 1H), 7.81-7.83 (d, 1H), 8.00 (t, 2H), 8.18 (d, 1H).

ESI MASS: 623.1, [M]⁺.

### Synthesis Example 4: Synthesis and Structural Characterization of Ir-4

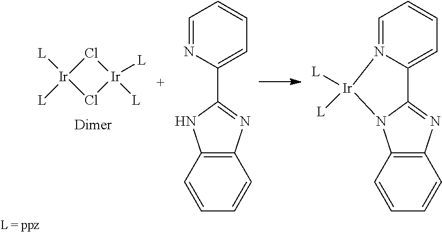

Dimer (0.1 g, 0.10 mmol, 1.0 eq), ligand (0.2 g, 1.0 mmol, 10.0 eq), potassium carbonate (0.3 g, 2.2 mmol, 22.0 eq), and ethylene glycol monomethyl ether (2 mL) are added into a seal tube (60 ml), the seal tube is air replaced with nitrogen for 5 times, then the mixture is heated to 120° C., allowed to react for 20 h, cooled to room temperature, filtered, and then rinsed with 10 mL water, 10 mL ethyl alcohol and 10 mL petroleum ether, respectively, and finally raw product is purified through chromatography with the eluent of DCM:MeOH=10:1 (volume ratio) to obtain 70 mg yellow solid with a yield of 52% and a UPLC purity of 98.5%.

A luminous spectrum of the obtained complex in DCM at room temperature is shown in FIG. 4, in which a main emission peak is at 516 nm. Thus, the obtained complex is a green light material.

¹H-NMR (300 MHz, CDCl₃) δ: 6.33-6.36 (d, 1H), 6.43-6.48 (m, 4H), 6.81 (d, 1H), 6.86-6.93 (m, 4H), 7.02-7.09 (m, 2H), 7.22 (s, 3H), 7.29 (s, 1H), 7.86-7.88 (d, 1H), 7.96-8.06 (m, 4H).

ESI MS: 674.2, [M+H]⁺.

### Synthesis Example 5: Synthesis and Structural Characterization of Ir-5

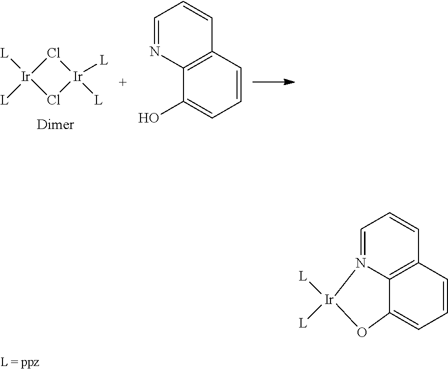

Dimer (0.1 g, 0.10 mmol, 1.0 eq), ligand (0.2 g, 1.4 mmol, 14.0 eq), potassium carbonate (0.3 g, 2.2 mmol, 22.0 eq), and ethylene glycol monomethyl ether (2 mL) are added into a seal tube (60 ml), the mixture is bubbled with nitrogen for 15 min, heated to 135° C., allowed to react for 20 h, cooled to room temperature, and filtered. The raw product is rinsed with 10 mL water, 10 mL ethyl alcohol and 10 mL petroleum ether respectively, and finally purified through chromatography with the eluent of DCM:MeOH=20:1 (volume ratio) to obtain 76 mg orange-yellow solid with a yield of 61%.

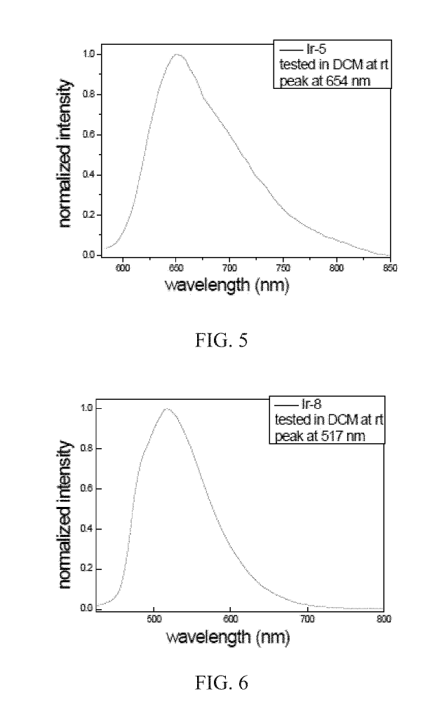

A luminous spectrum of the obtained complex in DCM at room temperature is shown in FIG. 5, in which a main emission peak is at 654 nm. Thus, the obtained complex is a red light material.

¹H-NMR (300 MHz, CDCl₃) δ: 6.35-6.49 (m, 4H), 6.68-6.78 (m, 4H), 6.81-6.90 (m, 2H), 6.95-6.98 (d, 1H), 7.03-7.09 (m, 1H), 7.13-7.18 (t, 2H), 7.35-7.40 (t, 1H), 7.68 (s, 1H), 7.76-7.79 (d, 1H), 7.97 (m, 3H).

ESI MS: 624.1, [M+H]⁺.

### Synthesis Example 6: Synthesis and Structural Characterization of Ir-8

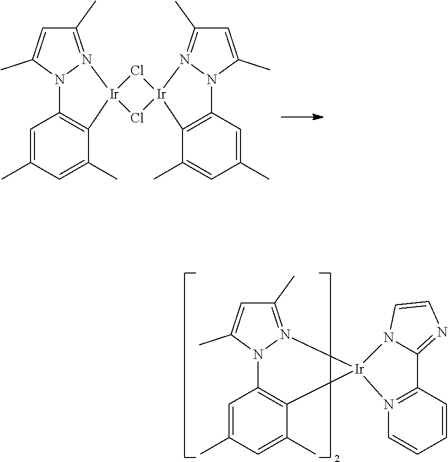

Dimer (0.1 g, 0.10 mmol, 1.0 eq), ligand (0.2 g, 1.4 mmol, 14.0 eq), potassium carbonate (0.3 g, 2.2 mmol, 22.0 eq), and ethylene glycol monomethyl ether (2 mL) are added into a seal tube (60 mL), the seal tube is air replaced with nitrogen for 5 times, heated to 120° C., allowed to react for 20 h, cooled to room temperature, filtered, and then rinsed with 30 mL EA, and finally the organic phase is purified through chromatography with the eluent of PE:EA=5:1 (volume ratio) to obtain 90 mg yellow solid with a yield of 72%.

A luminous spectrum of the obtained complex in DCM at room temperature is shown in FIG. 6, in which a main emission peak is at 517 nm. Thus, the obtained complex is a green light material.

¹H-NMR (300 MHz, DMSO) δ: 7.88 (d, J=7.5 Hz, 1H), 7.80 (t, J=7.7 Hz, 1H), 7.61 (d, J=5.5 Hz, 1H), 7.26 (d, J=14.5 Hz, 2H), 7.07 (t, J=6.0 Hz, 1H), 6.96 (s, 1H), 6.45 (d, J=17.1 Hz, 2H), 6.23 (s, 1H), 5.98 (d, J=11.2 Hz, 2H), 2.74 (d, J=3.7 Hz, 6H), 2.27 (d, J=2.0 Hz, 6H), 1.36 (s, 3H), 1.30 (s, 3H), 1.26 (d, J=1.4 Hz, 6H).

ESI MS: 736.3, [M+H]⁺.

### Synthesis Example 7: Synthesis and Structural Characterization of Ir-9

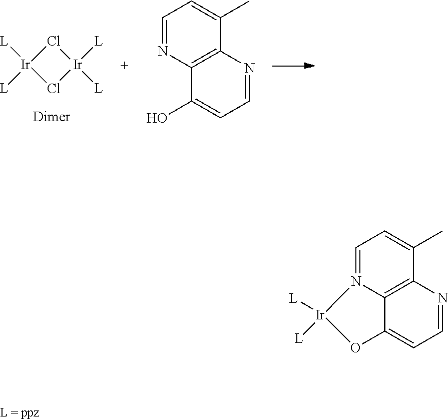

Dimer (0.1 g, 0.10 mmol, 1.0 eq), ligand (0.2 g, 9.3 mmol, 9.3 eq), potassium carbonate (0.3 g, 2.2 mmol, 22.0 eq), and ethylene glycol monomethyl ether (2 mL) are added into a seal tube (60 mL), the seal tube is air replaced with nitrogen for 5 times, heated to 120° C., allowed to react for 20 h, cooled to room temperature, filtered, and then rinsed with 30 ml EA, and finally the organic phase is purified through chromatography with the eluent of DCM:MeOH=30:1 (volume ratio) to obtain 50 mg yellow solid with a yield of 58%.

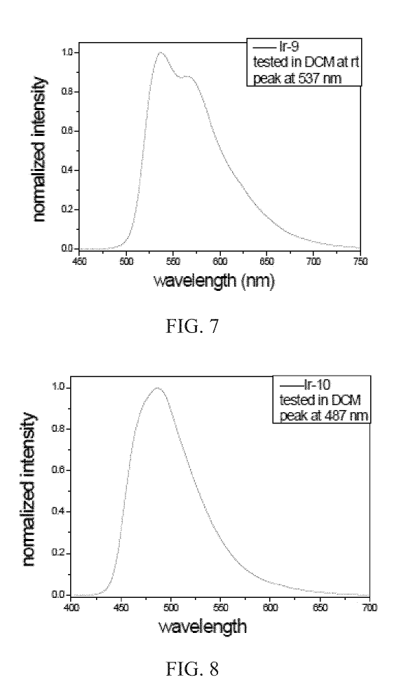

A luminous spectrum of the obtained complex in DCM at room temperature is shown in FIG. 7, in which a main emission peak is at 537 nm. Thus, the obtained complex is a yellow light material.

1H-NMR (300 MHz, DMSO) δ: 8.78 (dd, J=5.1, 2.9 Hz, 2H), 8.29 (d, J=5.5 Hz, 1H), 7.58 (dd, J=8.7, 3.9 Hz, 3H), 7.45 (dd, J=6.0, 4.0 Hz, 2H), 7.00-6.82 (m, 3H), 6.78-6.54 (m, 5H), 6.27 (d, J=7.5 Hz, 1H), 6.18 (d, J=7.3 Hz, 1H), 2.64 (s, 3H).

ESI MS: 639.1, [M+H]⁺.

### Synthesis Example 8: Synthesis and Structural Characterization of Ir-10

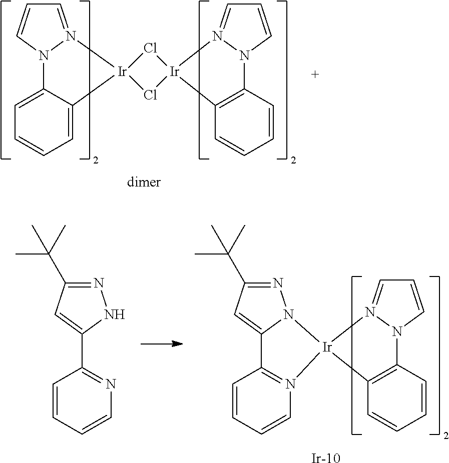

Dimer (0.1 g, 0.10 mmol, 1.0 eq), ligand (0.2 g, 1.0 mmol, 10.0 eq), potassium carbonate (0.3 g, 2.2 mmol, 22.0 eq), and ethylene glycol monomethyl ether (2 mL) are added into a seal tube (38 mL), and the seal tube is air replaced with nitrogen for 5 times. The mixture is heated to 120° C., allowed to react for 20 h, cooled to room temperature, filtered, and then sequentially rinsed with 30 mL EA and 30 mL DCM, and finally the DCM phase is purified through chromatography with the eluent of DCM:MeOH=30:1 (volume ratio) to obtain 30 mg light green solid with a yield of 44%.

A luminous spectrum of the obtained complex in DCM at room temperature is shown in FIG. 8, in which a main emission peak is at 487 nm. Thus, the obtained complex is a blue-green light material.

1H-NMR (300 MHz, DMSO-d⁶) δ: 8.77 (d, J=2.9 Hz, 1H), 8.66 (d, J=2.9 Hz, 1H), 7.79 (d, J=4.3 Hz, 2H), 7.74 (d, J=5.8 Hz, 1H), 7.50 (d, J=7.2 Hz, 2H), 7.02 (d, J=5.1 Hz, 1H), 6.97 (s, 1H), 6.89 (t, J=7.8 Hz, 1H), 6.82 (t, J=7.6 Hz, 1H), 6.75 (t, J=7.5 Hz, 1H), 6.63 (d, J=7.3 Hz, 2H), 6.56 (d, J=6.3 Hz, 2H), 6.39 (s, 1H), 6.20-6.01 (m, 2H), 1.19 (d, J=1.2 Hz, 9H).

ESI MS: 680.2, [M]⁺.

An energy level and a luminous performance of compound Ir-3 (Ir(ppz)₂(ImPy)) in the embodiment of the present disclosure is compared with an energy level and a luminous performance of an existing material Ir(ppz)₃.

ppz refers to

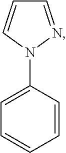 [SMILES: c1ccc(-n2cccn2)cc1]

and ImPy refers to

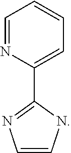

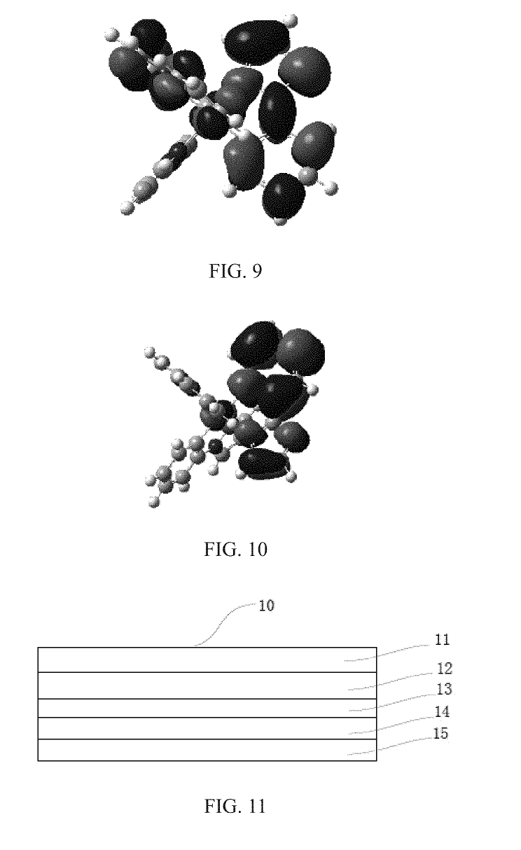

The molecular electron cloud structures of the two compounds at S₁ excited state are determined by calculating with density functional theory (DFT) using software Gaussian 09, and the results are shown in FIGS. 9 and 10. T₁ energy level is determined by energy of a peak of phosphorescent v₀₋₀ vibration emission spectrum at a low temperature of 77K.

Detailed experimental data is listed in Table 1.

TABLE 1

| | Electron Cloud | | Emission |
|---|---|---|---|
| | Structure at S₁ | T₁ Energy | Peak/Luminous |
| Complex | Excited State | Level | Efficiency in Solution |
| Ir (ppz)₃ | as shown in FIG. 9 | 3.00 eV | Non-luminous |
| Ir (ppz)₂(ImPy) | as shown in FIG. 9 | 2.70 eV | 493 nm/0.2 |

It's known from data listed in Table 1 that a conventional ancillary ligand (e.g., acetylacetonates) participates into an excited state transition and a radiation at a small degree, and the basic luminous property (spectrum and luminous efficiency) of the original ligand can be hardly influenced and changed. In the embodiments of the present disclosure, the excited-state-interfering ligand containing pyridine participates into a constitution of an electron excited state configuration at a great degree, so that ppz-Ir structure, which is non-luminous originally, can emit light at room temperature, and has a luminous efficiency of 20% in the solution. In addition, in the complexes provided by the present disclosure, the light-emitting spectrum is in a range from blue-green light (492 nm) to red light (654 nm), and a stable and highly efficient blue-green light phosphorescent material is obtained.

The organic metal complexes provided by the present disclosure are suitable for various organic electronic component, such as optical element and photoelectric element, including but not limited to organic light-emitting diode (OLED), light-emitting diode (LED), compact florescent lamp (CFL), incandescent lamp, organic photovoltaic cell (OPV), organic field effect transistor (OFET), and light-emitting electrochemical cell (LEEC).

In addition, the organic metal complex provided by the present disclosure can be used in biomarker or imaging technologies.

The organic metal complex provided by the present disclosure can be used in illumination elements, such as organic light-emitting element, with a higher efficiency and/or a longer service life than those of conventional materials.

The organic metal complex provided by the present disclosure can be used as phosphorescent light-emitting material and used in OLED, light-emitting element, display, and other light-emitting elements.

Specifically, the embodiment of the present disclosure further provides a light-emitting element. The light-emitting element is an OLED, and includes a first electrode, a second electrode opposite to the first electrode, a hole transmission layer, an electron transmission layer opposite to the hole transmission layer, and at least one organic layer. The hole transmission layer and the electron transmission layer are placed between the first electrode and the second electrode. The organic layer is placed between the hole transmission layer and the electron transmission layer. A structural schematic diagram of the light-emitting element in the embodiment is shown in FIG. 11. The light-emitting element 10 includes a first electrode 11, a hole transmission layer 12, a light-emitting layer 13, an electron transmission layer 14, and a second electrode 15. The first electrode 11, the hole transmission layer 12, the light-emitting layer 13, the electron transmission layer 14, and the second electrode 15 are sequentially formed by deposition. The hole transmission layer 12, the light-emitting layer 13, and the electron transmission layer 14 are organic layers. The first electrode 11 is electrically connected with the second electrode 15. The organic metal complex of the present disclosure is contained at least in the light-emitting layer 13.

The organic metal complex provided by the present disclosure can not only be used as phosphorescent light-emitting material, but also be used as base material, charge transfer material, and/or charge blocker.

The compound disclosed by the present disclosure presents desirable properties, and its emission spectrum and/or absorption spectrum can be adjusted by selecting adaptable ligand.

The luminous performance of the compound provided by the present disclosure is further illustrated with the light-emitting element as follows.

An ITO substrate is a bottom emission glass with a size of 30 mm×30 mm, and has four light-emitting areas. Light-emitting area AA is 2 mm×2 mm. A transmittance at 550 nm of the ITO film is 90%. A surface roughness Rₐ of the ITO film is smaller than 1 nm, a thickness of the ITO film is 1300 Å, and a square resistance of the ITO film is 10Ω/□.

A cleaning method for the ITO substrate: first, the ITO substrate is placed in a container with an acetone solution, and then the container is placed in an ultrasonic cleaning machine for ultrasonic cleaning for 30 min, to mainly remove and dissolve organics attached on the surface of the ITO substrate; second, the ITO substrate is taken out from the container and placed on a hot plate to be heated at 120° C. for 30 min, to mainly remove organic solution and moisture on the surface of the ITO substrate; then, the ITO substrate after being heated is rapidly transported to a UV-ZONE equipment to be performed O₃ plasma treatment for 15 min, to further treat hardly removed organics or foreign substance on the surface of the ITO substrate by plasma. After the plasma treatment, the ITO substrate should be rapidly transported to a film forming chamber of an OLED evaporation deposition equipment.

Preparation before OLED evaporation deposition: first, the OLED evaporation deposition equipment is cleaned by wiping an inner wall of the film forming chamber with IPA to guarantee no foreign substance or dust in the whole film forming chamber. Second, a crucible with OLED organic material and a crucible with metal aluminum particles are subsequently placed on a position of organic evaporation source and a position of inorganic evaporation source. Then, the chamber is closed and is evacuated initially and then highly so that a vacuum degree in the OLED evaporation deposition equipment reaches 10E⁻⁷ Torr.

OLED evaporation deposition: first, the organic evaporation source is started to preheat the OLED organic material at 100° C. for 15 min, to further remove moisture in the OLED organic material. Second, the organic material to be evaporated is rapidly heated, a blocking plate above the organic evaporation source is opened until all of the organic material of the organic evaporation source runs out; simultaneously, when an evaporation rate is detected by quartz monitor crystals, the organic evaporation source is gently heated with a rise of 1-5° C., until the evaporation rate is stabilized at 1 A/second, a blocking plate below a mask is opened to perform OLED deposition. When the computer observes that a thickness of an organic film on the ITO substrate reaches a preset thickness, the blocking plate below the mask and the blocking plate right above the evaporation source are closed, and an evaporation source heater of the organic material is closed. An evaporation deposition process of other organic materials and cathode metal materials are similar to process as described above.

An OLED packaging process: a cleaning process of a package cover with a size of 20 mm×20 mm is similar to the cleaning process of the pretreatment of the ITO substrate. UV adhesive coating or dispensing is performed on an outer periphery of the package cover after cleaning. Then, the package cover with UV adhesive is transferred to a vacuum lamination equipment, and vacuum laminated to the ITO substrate deposited with the OLED organic film, and then is transferred to a UV curing chamber to cure by UV light of 365 nm. The ITO element cured is further after-heated at 80° C. for 30 min so that the UV adhesive is cured thoroughly.

(I) For evaluating the electroluminescent property of the compound of the present disclosure, experiments are performed as follows.

1. Element No. A-C

The organic metal complexes Ir-8, Ir-9, and Ir-10 provided by the present disclosure are respectively used as phosphorescent light-emitting materials, and structures of OLED elements designed correspondingly are as follows:

ITO/NPB(30 nm)/TCTA(30 nm)/5 wt % Ir:TCTA(30 nm)/PPF(10 nm)/TPBi(30 nm)/Li F(0.8 nm)/Al(150 nm).

UV epoxy resin is used for photocuring packaging. Samples after being packaged are performed IVL performance test. Mc Science M6100 is used as an IVL equipment. The testing data is listed in Table 2.

2. Element No. F:

An existing blue light phosphorescent material fac-Ir(mpim)₃ is used in the OLED elements designed for comparison as follows:

ITO/NPB(30 nm)/TCTA(30 nm)/10 wt % fac-Ir(mpim)₃:90 wt % TCTA(30 nm)/PPF(10 nm)/TPBi(30 nm)/LiF(0.8 nm)/Al(150 nm).

UV epoxy resin is used for photocuring packaging. Samples after being packaged are performed IVL performance test. Mc Science M6100 is used as an IVL equipment. The testing data is also listed in Table 2.

TABLE 2

| | | | Maximum Current |
|---|---|---|---|
| Element | Organic Metal | Maximum | Efficiency |
| No. | Complex | EQE (%) | (cd/A) |
| A | Ir8 | 14.2 | 38 |
| B | Ir9 | 14.5 | 38 |
| C | Ir10 | 15.1 | 39 |
| F | Ir(mpim)₃ | 14.0 | 37 |

Thus, it can be seen that the light-emitting elements using the organic metal complexes provided by the present disclosure have higher luminous efficiencies.

Although the present disclosure is described with the preferred embodiments as above, these embodiments are not intended to limit the claims. The person skilled in the art is able to make several possible variations and modifications, without departing from the concept of the present disclosure. The protection scope of the present disclosure should be determined by the scope defined in the claims.

What is claimed is:

1. An organic metal complex selected from a group consisting of compounds represented by general formula I and combinations thereof; 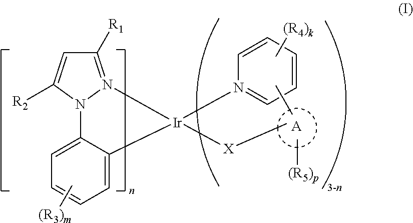
wherein R₁, R₂, R₃, R₄ and R₅ are independently selected from a group consisting of hydrogen, diplogen, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl;
R₂, R₄ and R₅ are independently and optionally connected with an adjacent aryl or substituent;
X represents carbon atom, oxygen atom, or nitrogen atom, structure A is selected from a group consisting of substituted or unsubstituted C₁-C₆ alkylene, substituted or unsubstituted C₃-C₃₆ heteroaromatic ring, and substituted or unsubstituted C₆-C₃₆ aromatic ring, and structure A is connected with or fused to a pyridine ring;
X is connected with structure A or is an atom in structure A;
n is 1 or 2, and m, k and p are integers independently selected from a group consisting of 1, 2, 3 and 4; and
each substituent is independently selected from a group consisting of halogen, C₁-C₆ alkyl, C₁-C₆ deuterated alkyl and combinations thereof.

2. The organic metal complex according to claim 1, wherein
when X is carbon atom, structure A is selected from a group consisting of substituted or unsubstituted C₃-C₃₆ heteroaromatic ring and substituted or unsubstituted C₆-C₃₆ aromatic ring, and X is an atom in structure A; or
when X is nitrogen atom, structure A is selected from a group consisting of substituted or unsubstituted C₃-C₃₆ heteroaromatic ring, and X is an atom in structure A; or
when X is oxygen atom, structure A is selected from a group consisting of substituted or unsubstituted C₁-C₆ alkylene, substituted or unsubstituted C₃-C₃₆ heteroaromatic ring, and substituted or unsubstituted C₆-C₃₆ aromatic ring, and X is connected with structure A.

3. The organic metal complex according to claim 1, wherein the organic metal complex is selected from a group consisting of compounds represented by general formula IA and combinations thereof; 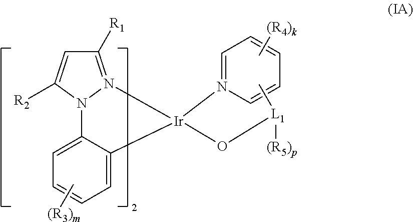
wherein L₁ is selected from a group consisting of substituted or unsubstituted C₁-C₆ alkylene, substituted or unsubstituted C₃-C₃₆ heteroaromatic ring, and substituted or unsubstituted C₆-C₃₆ aromatic ring; and L₁ is connected with or fused to the pyridine ring.

4. The organic metal complex according to claim 3, wherein the organic metal complex is selected from a group consisting of compounds represented by general formula IAa and general formula IAb, and combinations thereof; 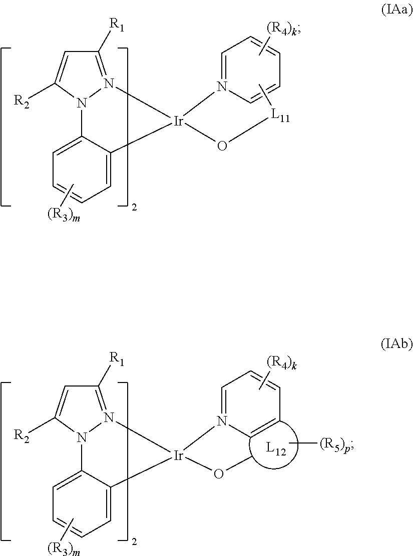
wherein L₁₁ is selected from a group consisting of substituted or unsubstituted C₁-C₆ alkylene, and L₁₂ is selected from a group consisting of substituted or unsubstituted C₃-C₁₈ heteroaromatic ring and substituted or unsubstituted C₆-C₁₈ aromatic ring,
each substituent is independently selected from a group consisting of halogen, C₁-C₆ alkyl, C₁-C₆ deuterated alkyl and combinations thereof.

5. The organic metal complex according to claim 1, wherein the organic metal complex is selected from a group consisting of compounds represented by general formula IB and combinations thereof; 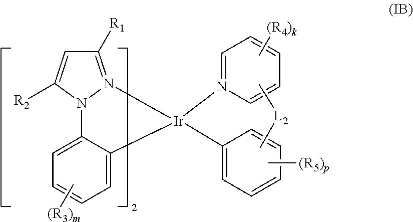
wherein L₂ is selected from a group consisting of substituted or unsubstituted C₁-C₆ alkylene, substituted or unsubstituted C₃-C₃₆ heteroaromatic ring and substituted or unsubstituted C₆-C₃₆ aromatic ring, and L₂ is connected with or fused to a pyridine ring and L₂ is connected with or fused to a benzene ring, and
each substituent is independently selected from a group consisting of halogen, C₁-C₆ alkyl, C₁-C₆ deuterated alkyl and combinations thereof.

6. The organic metal complex according to claim 5, wherein the organic metal complex is selected from a group consisting of compounds represented by general formula IBa, general formula IBb and general formula IBc, and combinations thereof; 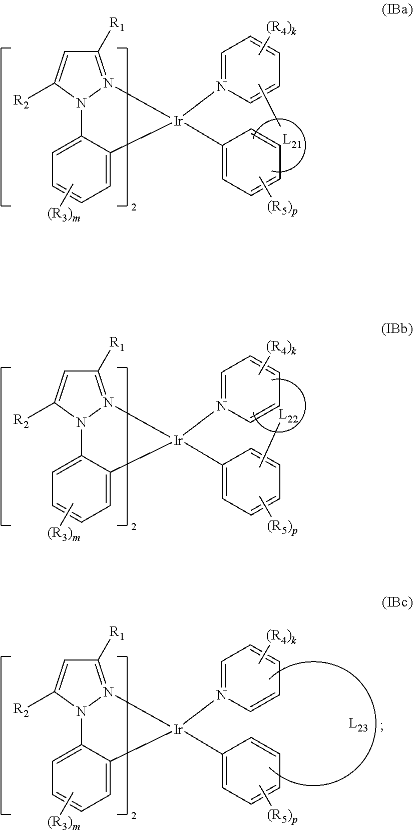
wherein L₂₁, L₂₂ and L₂₃ are independently selected from a group consisting of substituted or unsubstituted C₁-C₆ alkylene, substituted or unsubstituted C₃-C₁₈ heteroaromatic ring, and substituted or unsubstituted C₆-C₁₈ aromatic ring;
L₂₁ is fused to a benzene ring, L₂₂ is fused to a pyridine ring, and L₂₃ is fused to both a pyridine ring and a benzene ring; and
each substituent is independently selected from a group consisting of halogen, C₁-C₆ alkyl, C₁-C₆ deuterated alkyl and combinations thereof.

7. The organic metal complex according to claim 1, wherein the organic metal complex is selected from a group consisting of compounds represented by general formula IC and combinations thereof; 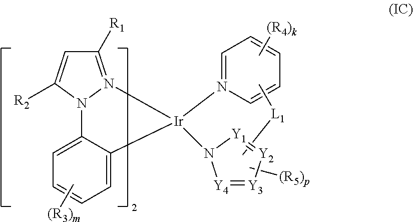
wherein Y₁, Y₂, Y₃ and Y₄ are independently selected from a group consisting of nitrogen atom and carbon atom;
L₃ is selected from a group consisting of a dummy atom, substituted or unsubstituted C₁-C₆ alkylene, substituted or unsubstituted C₃-C₃₆ heteroaromatic ring, and substituted or unsubstituted C₆-C₃₆ aromatic ring;
L₃ is connected with or fused to a five membered ring and L₃ is connected with or fused to a pyridine ring; and
each substituent is independently selected from a group consisting of halogen, C₁-C₆ alkyl, C₁-C₆ deuterated alkyl and combinations thereof.

8. The organic metal complex according to claim 7, wherein the organic metal complex is selected from a group consisting of compounds represented by general formula ICa and general formula ICb, and combinations thereof; 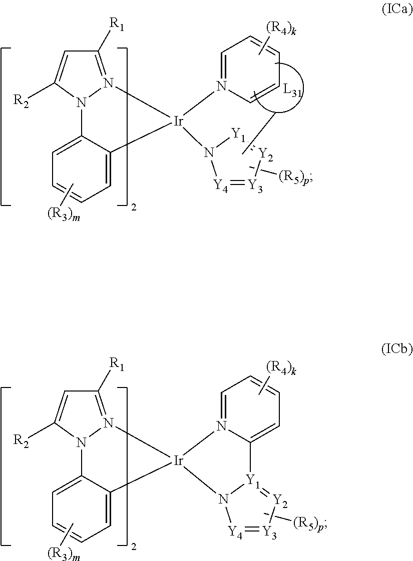
wherein L₃₁ is selected from a group consisting of substituted or unsubstituted C₃-C₁₈ heteroaromatic ring and substituted or unsubstituted C₆-C₁₈ aromatic ring; and
each substituent is independently selected from a group consisting of halogen, C₁-C₆ alkyl, C₁-C₆ deuterated alkyl and combinations thereof.

9. The organic metal complex according to claim 1, wherein a ligand on a right side of the general formula I is selected from a group of consisting of structures as follows: 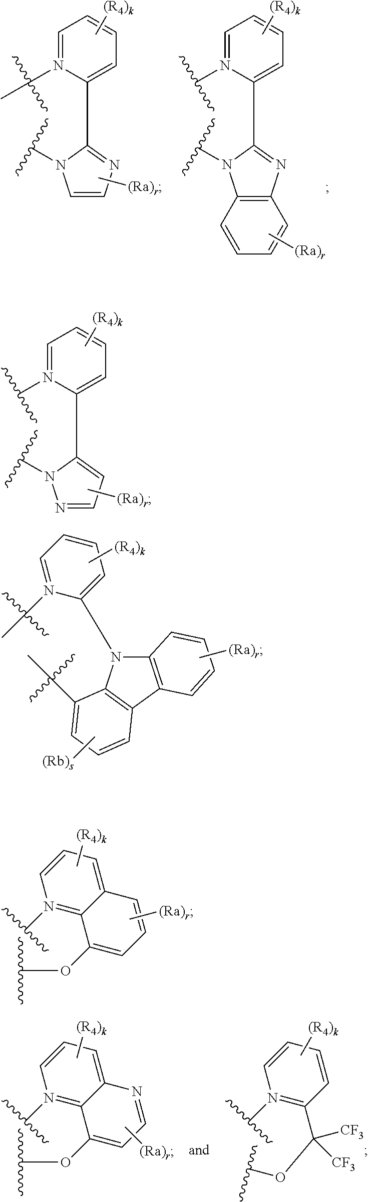
wherein Rₐ and R_{b} are selected from a group consisting of hydrogen, diplogen, substituted or unsubstituted C₁-C₆ alkyl, substituted or unsubstituted C₁-C₆ deuterated alkyl, substituted or unsubstituted C₆-C₃₆ aryl, and substituted or unsubstituted C₆-C₃₆ deuterated aryl;
Rₐ and R_{b} are independently and optionally connected with an adjacent aryl or substituent; and
r and s are integers independently selected from a group consisting of 1, 2, 3 and 4.

10. The organic metal complex according to claim 9, wherein the ligand on the right side of the general formula I is selected from a group of consisting of structures as follows:

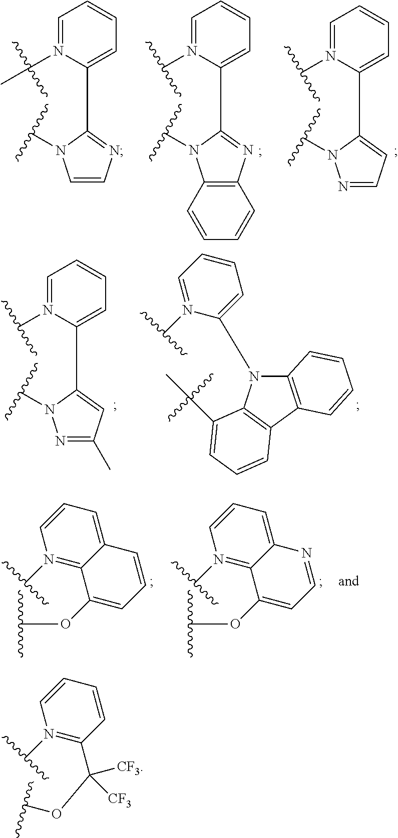

11. The organic metal complex according to claim 1, wherein a ligand on a left side of the general formula I is selected from a group consisting of structures as follows: 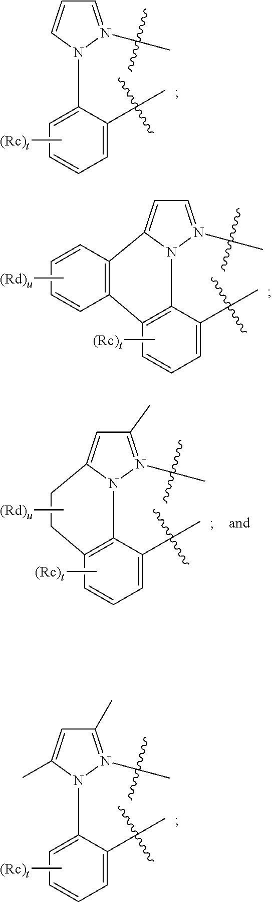
wherein R_{c} and R_{d} are selected from a group consisting of hydrogen, diplogen, substituted or unsubstituted C₁-C₆ alkyl, substituted or unsubstituted C₁-C₆ deuterated alkyl, substituted or unsubstituted C₆-C₃₆ aryl, and substituted or unsubstituted C₆-C₃₆ deuterated aryl;
R_{c} and R_{d} are independently and optionally connected with an adjacent aryl or substituent; and
t and u are integers independently selected from a group consisting of 1, 2, 3 and 4.

12. The organic metal complex according to claim 11, wherein the ligand on the left side of the general formula I is selected from a group consisting of structures as follows:

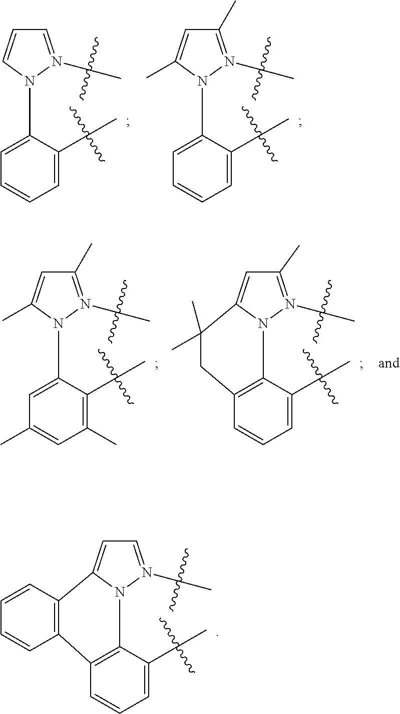

13. The organic metal complex according to claim 1, wherein the organic metal complex is selected from a group consisting of compounds represented by general formulas as follows and combinations thereof:

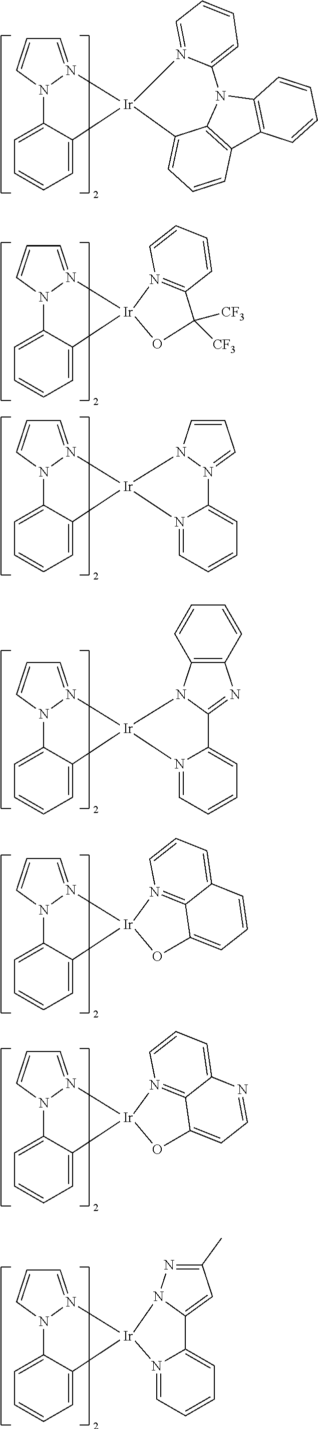

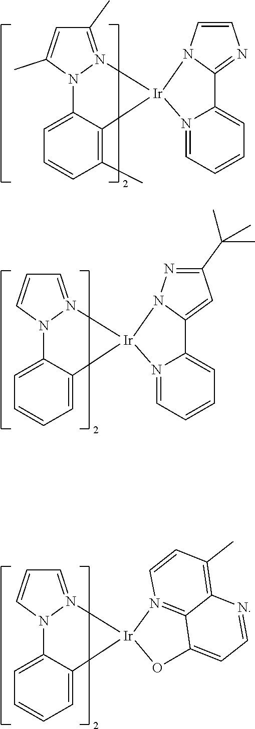

14. A method for preparing the organic metal complex according to claim 1, comprising at least steps of:
reacting a precursor with iridium chloride to obtain a dimer; and
reacting the dimer with a ligand compound to obtain the organic metal complex represented by general formula I;
a chemical reaction equation of the method is shown as below:

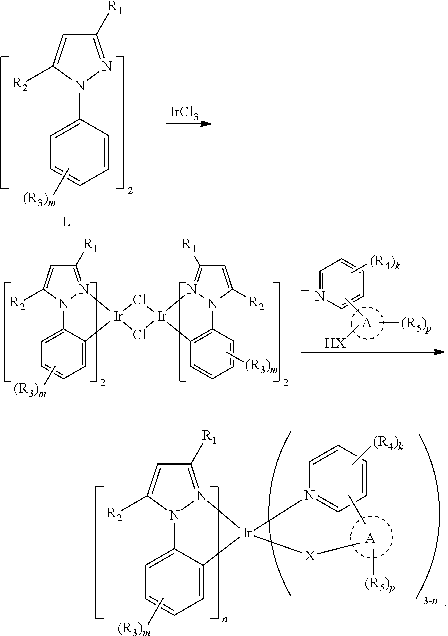

15. A light-emitting element, comprising a first electrode, a second electrode, and at least one organic layer placed between the first electrode and the second electrode, wherein the organic layer comprises the organic metal complex according to claim 1.
